(19) United States
(12) Patent Application Publication
(10) Pub. No.: US 2020/0149639 A1
(43) Pub. Date: May 14, 2020

(54) VALVE DEVICE

(71) Applicant: FUJIKIN INCORPORATED, Osaka (JP)

(72) Inventors: Kenji AIKAWA, Osaka (JP); Tsutomu SHINOHARA, Osaka (JP); Takahiro MATSUDA, Osaka (JP)

(73) Assignee: FUJIKIN INCORPORATED, Osaka (JP)

(21) Appl. No.: 16/625,875

(22) PCT Filed: Jun. 12, 2018
(86) PCT No.: PCT/JP2018/022440

§ 371 Date: Dec. 23, 2019

(30) Foreign Application Priority Data
Jun. 30, 2017 (JP) 2017-129016

(51) Int. Cl. F16K 7/17; F16K 47/00; F16F 15/00; F16F 15/073; H01L 41/04; H01L 41/08

(52) U.S. Cl. CPC F16K 7/17; F16K 47/00; H01L 41/0825; F16F 15/073; H01L 41/042; F16F 15/007

(57) ABSTRACT

To provide a gas-driven type valve device that is capable of mounting various electronic devices, and includes a power generation function that solves problems involving wiring or battery replacement. The problem is solved by a valve device including an actuator including a housing part, and a movable part housed in the housing part and driven by a driving fluid to move a valve element in a closing direction or an opening direction, a spring member that presses the movable part in a direction against a driving force of the driving fluid, and a power-generating and vibration-damping unit including that uses a piezoelectric effect of a piezoelectric element to exercise a power generation function of converting a vibration generated in a vibration system by an activation of the actuator into electric power, and a vibration-damping function of suppressing a vibration applied to a device.

### FIELD OF THE INVENTION

The present invention relates to a valve device.

### DESCRIPTION OF THE BACKGROUND ART

In the field of valve devices as well, an electronic device such as a pressure sensor or a wireless module is mounted to increase the functionality of the device (refer to Patent Documents 1, 2, and 3). As means for supplying electric power used in these electronic devices, a method for driving various sensors using a button battery is disclosed in Patent Document 2. Further, in Patent Document 3, a system is disclosed in which a controller transmits to an electromagnetic valve a high frequency waves superimposed on a control input signal, and the valve extracts the high frequency component from the input control signal to receive a power.

### PATENT DOCUMENTS

Patent Document 1: JP 2011-513832 A

Patent Document 2: JP 2016-513228 A

Patent Document 3: JP 2017-020530 A

### SUMMARY OF THE INVENTION

### Problems to be Solved by the Invention

Even with an air-driven type valve device using air pressure, that is used in a semiconductor manufacturing system, there is a demand to have a power source for operating the various electronic devices.

As one means, it is conceivable to introduce a wiring for a power source from the outside to the valve device. However, in a fluid control system in which a large number of valves are installed, the wiring is not only complicated but, requires careful design and arrangement of the wiring to attend explosion-proof problems.

Further, as one means, a battery is used as a power source to solve problems involving wiring. However, this requires a primary battery with a capacity sufficient to meet the service life of the valve device, or the task of regular battery replacement.

The high-frequency superimposed power transmission to the electromagnetic valve in Patent Document 3 cannot be applied to a valve device that is an air-driven type.

A valve device used in a semiconductor manufacturing system is, for example, installed near a vibration source such as a vacuum pump, for example. Thus, while the semiconductor manufacturing system is in operation, the valve device is constantly subjected to external environmental vibrations. When the valve device is subjected to environmental vibrations, the valve element is also subjected to vibrations, which may affect the flow rate. In order to enable more precise flow rate control, the influence of environmental vibrations cannot be ignored.

An object of the present invention is to provide a valve device that can mount various electronic devices, includes a power generation function to solve problems involving wiring or battery replacement, and can suppress the influence of environmental vibrations.

### Means for Solving the Problems

A valve device according to the present invention comprises an actuator including a housing part, and a movable part housed in the housing part and driven by a driving fluid to move a valve element in a closing direction or an opening direction, a spring member that presses the movable part in a direction against a driving force of the driving fluid, and a power-generating and vibration-damping unit that uses a piezoelectric effect of a piezoelectric element to exercise a power generation function of converting a vibration generated in a vibration system by an activation of the actuator into electric power, and a vibration-damping function of suppressing a vibration applied to a device.

Preferably, a configuration can be adopted in which the valve device further includes an adjusting circuit formed so that dynamic characteristics of the vibration system can be controlled in accordance with a vibration applied from the outside of the device.

### Effect of the Invention

According to the present invention, a power-generating and vibration-damping unit can generate electricity by converting a vibration of a vibration system into electric power, making it possible to obtain a valve device that solves problems involving wiring or battery replacement. In addition, the power-generating and vibration-damping unit can suppress vibrations such as environmental vibrations applied from the outside of the valve device by the vibration-damping function.

### BRIEF DESCRIPTION OF THE DRAWINGS

FIG. 1A is an external perspective view of a valve device according to an embodiment of the present invention.

FIG. 1B is a perspective view including a longitudinal section of the valve device in FIG. 1A.

FIG. 1C is a longitudinal sectional view of the valve device in FIG. 1A.

FIG. 2 is an enlarged perspective view of a power-generating and vibration-damping unit.

FIG. 3A is a side view of the power-generating and vibration-damping unit.

FIG. 3B is a perspective view of the power-generating and vibration-damping unit in FIG. 3A.

FIG. 4 is a functional block diagram schematically illustrating an example of a load circuit.

FIG. 5 is a functional block diagram schematically illustrating another example of a load circuit.

### DESCRIPTION OF THE PREFERRED EMBODIMENTS

Embodiments of the present invention are described below with reference to the drawings. It should be noted that, in this specification and the drawings, components having substantially the same function are denoted using the same reference numeral, and duplicate descriptions thereof are omitted.

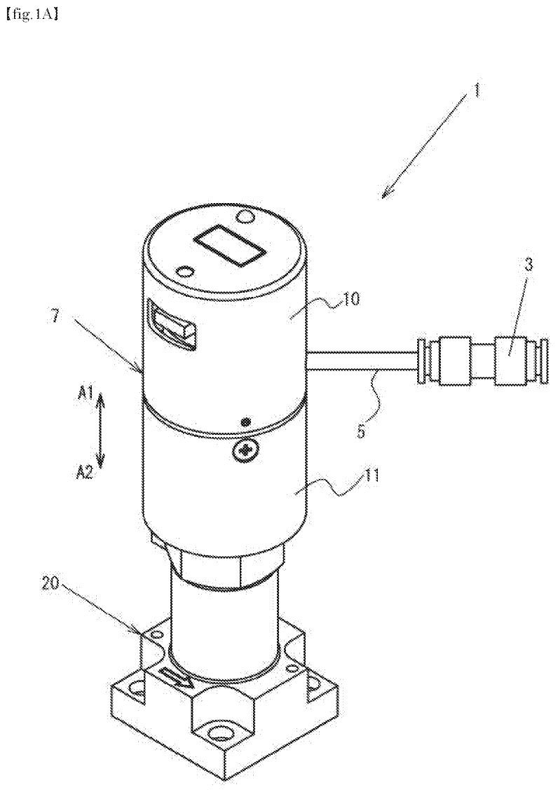

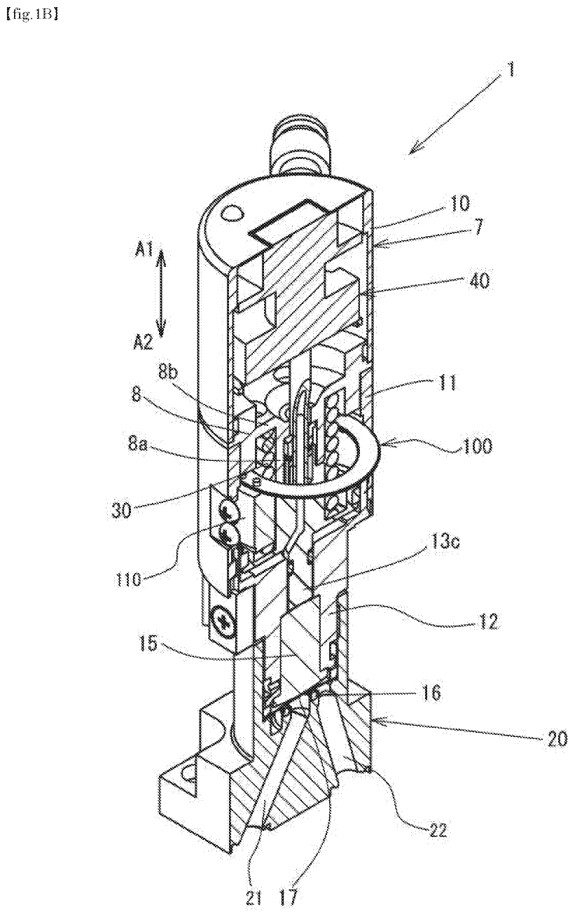

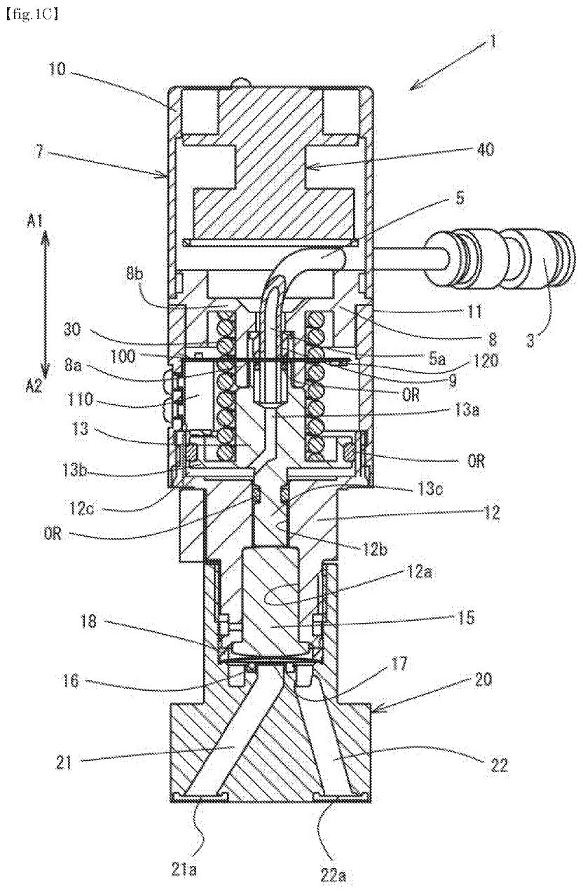

FIGS. 1A to 1C are drawings illustrating a configuration of a valve device according to an embodiment of the present invention, FIG. 1A being an external perspective view, FIG. 1B being a perspective view including a longitudinal section, and FIG. 1C being a longitudinal sectional view. It should be noted that, in the drawings, arrows A1, A2 indicate upward and downward directions, A1 being the upward direction and A2 being the downward direction.

A valve device 1 includes an actuator part 7 and a valve body 20. A pipe 5 with a pipe joint 3 connected to one end portion is introduced into an interior of the actuator part 7. Through the pipe 5, a driving fluid is supplied to the interior of the actuator part 7 or an air released from the actuator part 7 is discharged to the outside. As the driving fluid, for example, compressed air is used.

The actuator part 7 includes an actuator cap 10 having a cylindrical shape with an upper end part thereof closed, an actuator case 11 having a cylindrical shape, an actuator body 12, a piston member 13, a diaphragm presser 15, a coil spring 30, and a power-generating and vibration-damping unit 100.

The actuator cap 10 has a lower end part fixed to a spring receiving member 8 formed into an annular shape, and is provided with a circuit housing part 40 in the internal space. In FIGS. 1B and 1C, while the cross section of the circuit housing part 40 is indicated by hatching, the circuit housing part 40 is actually a cavity that houses an electrical element such as an electric circuit or a secondary battery. The pipe 5 is introduced into the interior of the actuator part 7 through the actuator cap 10.

The actuator case 11 supports the spring receiving member 8 on an upper end side thereof, and is screwed and fixed to the actuator body 12 on a lower end side thereof.

The actuator body 12, as illustrated in FIG. 1C, includes a guide hole 12a that guides the diaphragm presser 15 in the upward and downward directions A1, A2 at a lower side thereof, and is communicated to an upper side of the guide hole 12a to form a through hole 12b. A cylinder chamber 12c that slidably guides a flange part 13b of the piston member 13 in the upward and downward directions A1, A2 via an O-ring OR is formed on an upper side of the actuator body 12.

The piston member 13 includes a flow channel 13a communicating to the cylinder chamber 12c in a central portion. The flow channel 13a communicates with a pipeline 5a of a pipe 5. The flange part 13b and a tip end shaft part 13c of the piston member 13 freely moves through the cylinder chamber 12c and the through hole 12b in the upward and downward directions A1, A2 via the O-ring OR. A member 9 having a cylindrical shape is provided to an upper end part of the piston member 13, and restricts the movement of the O-ring OR that seals an area between the member 9 and the pipeline 5a of the pipe 5.

The diaphragm presser 15 is movable in the upward and downward directions A1, A2 by the guide hole 12a of the actuator body 12.

The valve body 20 is screwed with a lower side of the actuator body 12 at an upper side, and defines flow paths 21, 22 of a gas or the like that include openings 21a, 22a on bottom surfaces thereof. The flow paths 21, 22 are connected with other flow path members via a seal member (not illustrated).

A valve seat 16 is provided around the flow path 21 of the valve body 20. The valve seat 16 is formed from a resin such as a perfluoroalkoxyalkane (PFA) or a polytetrafluoroethylene (PTFE) in an elastically deformable manner.

A diaphragm 17 functions as a valve element, has a larger diameter than the valve seat 16, and is formed in an elastically deformable manner into a spherical shell shape of a metal such as stainless steel or an NiCo-based alloy, or a fluorine-based resin. The diaphragm 17 is supported by the valve body 20 so as to allow contact with and separation from the valve seat 16 by being pressed toward the valve body 20 by a lower end surface of the actuator body 12 via a pressing adapter 18. In FIG. 1C, the diaphragm 17 is in a state of being pressed by the diaphragm presser 15, elastically deformed, and pressed against the valve seat 16. When the pressing by the diaphragm presser 15 is released, the diaphragm 15 is restored into a spherical shell shape. The flow path 21 is closed in a state in which the diaphragm 17 is pressed against the valve seat 16 and, is released and communicates with the flow path 22 when the diaphragm 17 is separated from the valve seat 16.

The coil spring 30 is provided around a cylindrical portion 8a provided at a center of the spring receiving member 8, is interposed between a spring receiving part 8b of the spring receiving member 8 and the flange part 13b of the piston member 13, and continually presses the piston member 13 in the downward direction A2 by a restoring force. As a result, an upper end surface of the diaphragm presser 15 is pressed in the downward direction A2 by the piston member 13, and the diaphragm 17 is pressed toward the valve seat 16.

The power-generating and vibration-damping unit 100 is fixed to an inner peripheral surface of the actuator case 11 via a support member 110.

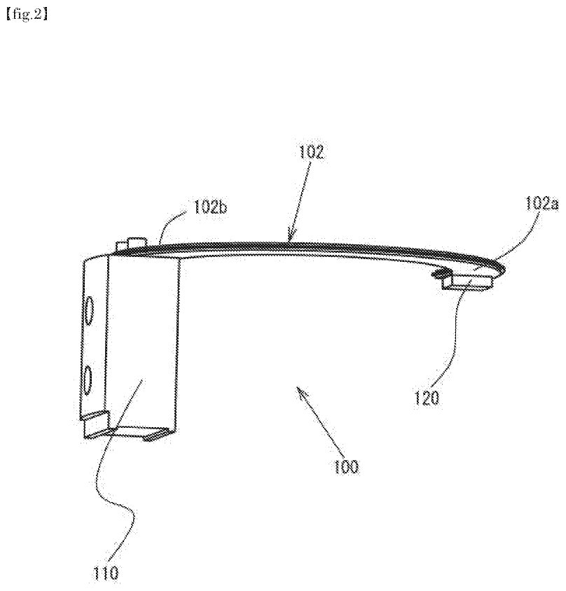

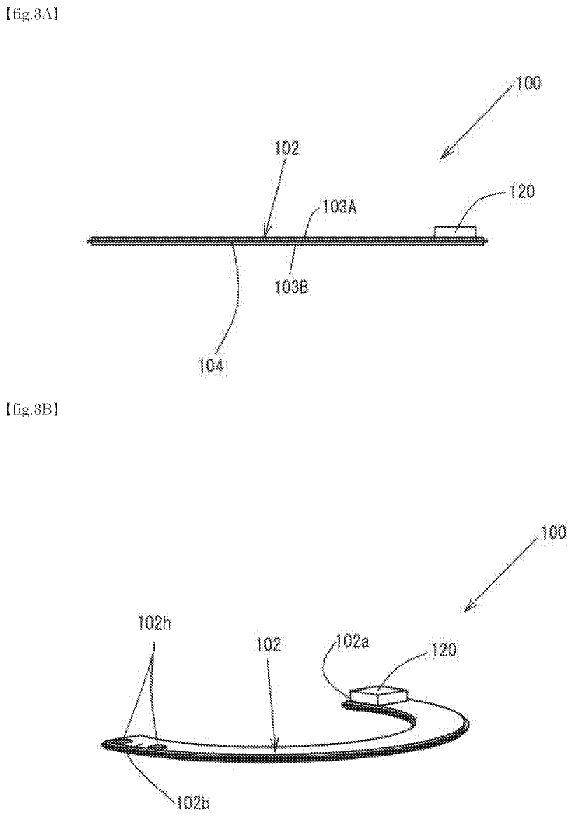

Here, FIGS. 2, 3A, and 3B illustrate a structure of the power-generating and vibration-damping unit 100.

The power-generating and vibration-damping unit 100 includes a piezoelectric bimorph 102 formed into an arc shape so as to fit in a space between an outer periphery of the coil spring 30 and the inner peripheral surface of the actuator case 11, the support member 110 that supports a base end part 102b of the piezoelectric bimorph 102 on the flange part 13b, and a mass part 120 provided at a tip end part 102a of the piezoelectric bimorph 102. The base end part 102b of the piezoelectric bimorph 102 is formed with an attaching hole 102h and is fixed to an upper surface of the support member 110 by a screw member, the tip end part 102a of the piezoelectric bimorph 102 is a free end, and the piezoelectric bimorph 102 constitutes an elastic deformation part having a cantilevered shape.

The piezoelectric bimorph 102 includes a metal plate 104 that is thin and is for maintaining mechanical strength, and piezoelectric elements 103A, 103B that are sheet-like members and provided on a front and a back of the metal plate 104. The piezoelectric elements 103A, 103B are electrically connected to a load circuit 600 described later. When the piezoelectric bimorph 102 is bent, the piezoelectric elements 103A, 103B are compressed or expanded and an electromotive force corresponding to the amount of this deformation is generated. Electric power can be differentially extracted from the piezoelectric elements 103A, 103B by the load circuit 600 described later.

Due to a structure such as one described above, the power-generating and vibration-damping unit 100 forms a vibration system that continues vibration-damping to generate electricity for a while when an impact is applied by a vertical movement of the piston member 13. Specifically, the piston member 13 is raised in the upward direction A1 by the supply of compressed air, which is a driving fluid, and an impact is produced when movement is restricted at a predetermined position. Further, when the compressed air is released, an impact is produced when the diaphragm presser 15 collides with the valve seat 16 via the diaphragm 17 due to the restoring force of the coil spring 30. Furthermore, even when the piston member 13 stops between fully opened and fully closed for use in an intermediate open state, or when the piston member 13 starts to move for opening and closing operations, a small impact is produced. Due to these impacts, vibration is generated in the power-generating and vibration-damping unit 100. Accordingly, in order to absorb the vibration in an operation direction of the piston member 13, a surface of the piezoelectric bimorph 102 is attached so as to be substantially perpendicular to an axis of the piston member 13.

In order to secure the amount of power generation, it is preferable that the area of the power-generating and vibration-damping unit 100 is as large as possible. In this embodiment, the power-generating and vibration-damping unit 100 is formed into an arc shape, and is housed in a space between the outer periphery of the coil spring 30 and the inner peripheral surface of the actuator case 11, enabling an arrangement in which the power-generating and vibration-damping unit 100 increases area while being incorporated into the valve device 1 and deviation of a center of gravity of the piston member 13 is reduced to the extent possible. It should be noted that the shape of the power-generating and vibration-damping unit 100 is not necessarily limited to an arc shape, and may be formed into, for example, an annular shape. The same cantilever structure can be obtained by fixing any point of the annular shape to the support member 110 as one end portion, and providing a mass part 120 on an opposite side of the annulus. Further, a rigidity of the piezoelectric bimorph 102 and a size of the mass part 120 can be set according to a desired natural frequency.

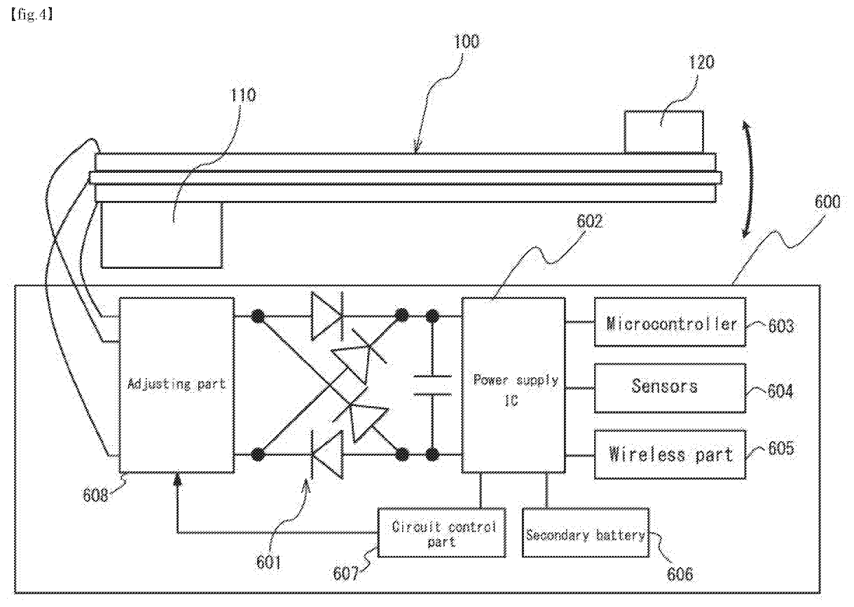

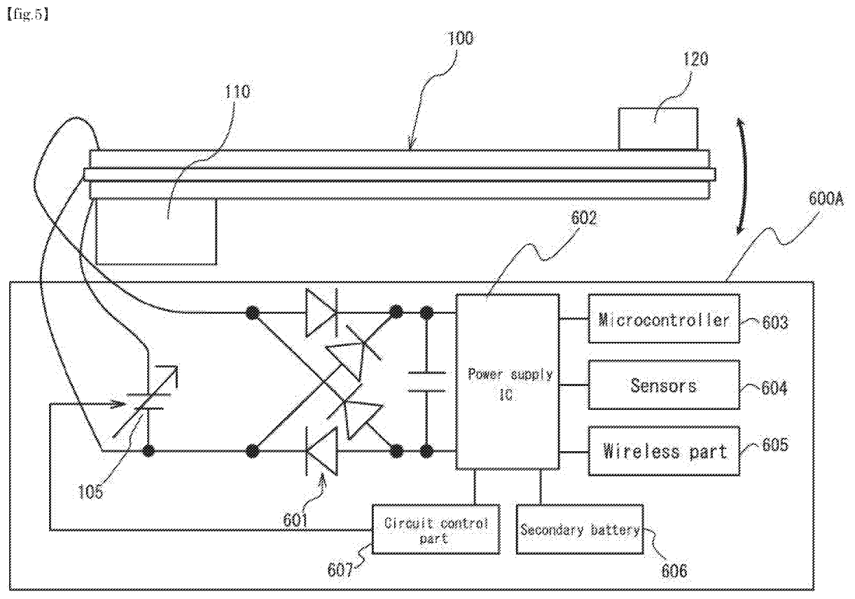

FIG. 4 illustrates an example of the load circuit 600 as a functional block diagram.

The load circuit 600 includes a rectifier circuit 601, a power supply integrated circuit (IC) 602, a microcontroller 603, various sensors 604 such as a pressure sensor, a temperature sensor, and an acceleration sensor, a wireless part 605 capable of transmitting data detected by the various sensors 604 to the outside, a secondary battery 606, a circuit control part 607, and an adjusting part 608 controlled by this circuit control part 607.

The rectifier circuit 601 converts an alternating current generated in the power-generating and vibration-damping unit 100 into a direct current through the adjusting part 608.

The power supply IC 602 functions as a power management IC that regulates electric power transmitted to a power supply destination such as the microcontroller 603, the various sensors 604, or the wireless part 605, while converting and storing the voltage of the electric power from the power-generating and vibration-damping unit 100 in the secondary battery 606. For example, as the power supply IC 602, a power supply IC commonly available for energy harvesting can be adopted.

The secondary battery 606 stores direct current power supplied from the power supply IC 602. A capacitor having a relatively large capacity can also be used in place of the secondary battery.

The circuit control part 607 outputs a control signal for controlling the adjusting part 608.

The adjusting part 608 selectively switches between the power generation function and the vibration-damping function of the power-generating and vibration-damping unit 100 in accordance with a control signal from the circuit control part 607.

Components other than the various sensors are housed in the circuit housing part 40, and the various sensors are disposed near the flow path or the like of the valve device 1 to detect pressure, temperature, and vibration, and are electrically connected by wiring with the power supply IC 602 and the microcontroller 603.

### Vibration-Damping Function

As described above, the power-generating and vibration-damping unit 100 can differentially extract voltage by generating voltage by the deformation of the piezoelectric elements 103A, 103B. That is, a power generation function is provided.

In addition, when voltage is appropriately applied to the piezoelectric elements 103A, 103B, the power-generating and vibration-damping unit 100 can apply a bending force to the piezoelectric bimorph 102. That is, the piezoelectric elements 103A, 103B are actuators, and apply voltage to the piezoelectric elements 103A, 103B through the adjusting part 608, making it possible to control the vibration of the piezoelectric bimorph 102.

FIG. 5 illustrates an example of another load circuit 600A as a functional block diagram. It should be noted that, in FIG. 5, the same components as those in FIG. 4 are denoted using the same reference numerals as in FIG. 4.

As illustrated in FIG. 5, the direct current voltage applied to the piezoelectric element 103B is changed by a direct current voltage adjusting part 105 while an alternating current power generated by the power-generating and vibration-damping unit 100 is measured by the power supply IC 602, making it possible to hold at a direct current voltage that maximizes the alternating current power generated by the piezoelectric element 103A. The efficiency of power generation and vibration-damping can be increased by configuring the power-generating and vibration-damping unit 100 to be resonant with a frequency that, among environmental vibrations, has a large influence and converting the energy of the vibration into electric power.

Further, for example, when an environmental vibration from the outside is applied to the valve device 1, the environmental vibration can be detected by the acceleration sensor of the sensors 604, and the piezoelectric elements 103A, 103B can be subjected to feedback control (active vibration-damping) so as to eliminate the environmental vibration. When the power-generating and vibration-damping unit 100 exhibits the vibration-damping function, a necessary low vibration environment can be formed.

By incorporation of the power-generating and vibration-damping unit 100 having such power-generating and vibration-damping functions into the valve device 1, the functions of the valve device 1 can be enhanced. It should be noted that the timing at which the vibration-damping function is exhibited is arbitrary and not necessarily limited to when an environmental vibration is applied such as described above. It is also possible to activate vibration-damping control during piston activation to significantly alleviate the impact, and generate power using environmental vibrations from the outside and applied when the valve is released. Further, needless to say, as a specific method of vibration-damping control, a known method can be adopted as appropriate. Furthermore, a configuration may be adopted in which only the power generation function or only the vibration-damping function of the power-generating and vibration-damping unit 100 is used.

While a so-called normally closed valve is given as an example in the above-described embodiment, the present invention is not necessarily limited thereto and can be applied to a so-called normally opened valve as well.

While a case where the valve device 1 is driven by compressed air is given as an example in the above-described embodiment, a gas other than air can also be used.

While a diaphragm-type valve is given as an example in the above-described embodiment, the present invention is not necessarily limited thereto and can be applied to other types of valves as well.

While a case where a bimorph-type power-generating and vibration-damping unit is used is described in the above-described embodiment, the present invention is not limited thereto, and a monomorph type can also be adopted. Further, the power-generating and vibration-damping unit can also be configured by combining multilayered-type piezoelectric elements, springs, and masses.

While a case where the piezoelectric bimorph serving as the power-generating and vibration-damping unit is only a single piezoelectric bimorph is given as an example in the above-described embodiment, a configuration can also be adopted in which a plurality of piezoelectric bimorphs are attached to different locations.

### DESCRIPTIONS OF REFERENCE NUMERALS

1 Valve device
5 Pipe
7 Actuator part (Actuator)
10 Actuator cap (Housing part)
11 Actuator case (Housing part)
12 Actuator body (Housing part)
13 Piston member (Movable part)
15 Diaphragm presser
16 Valve seat
17 Diaphragm (Valve element)
18 Pressing adapter
20 Valve body (Housing part)
30 Coil spring (Spring member)
100 Power-generating and vibration-damping unit
102 Piezoelectric bimorph (Elastic deformation part)
102a Tip end part
102b Base end part
102h Attaching hole
103A, 103B Piezoelectric element
104 Metal plate
105 Direct current voltage adjusting part
110 Support member
120 Mass part
600, 600A Load circuit

1. A valve device comprising:
an actuator including a housing part, and a movable part housed in the housing part and driven by a driving fluid to move a valve element in a closing direction or an opening direction;
a spring member that presses the movable part in a direction against a driving force of the driving fluid; and
a power-generating and vibration-damping unit that uses a piezoelectric effect of a piezoelectric element to exercise a power generation function of converting a vibration generated in a vibration system by an activation of the actuator into electric power, and a vibration-damping function of suppressing a vibration applied to a device.

2. The valve device according to claim 1, further comprising:
an adjusting circuit formed so that dynamic characteristics of the vibration system can be controlled in accordance with a vibration applied from the outside of the device.

3. The valve device according to claim 2, wherein
the adjusting circuit comprises a direct current voltage adjusting part that adjusts a direct current voltage applied to the piezoelectric element.

4. The valve device according to claim 1, wherein
a vibration system of the power-generating and vibration-damping unit comprises an elastic deformation part having a cantilevered shape with one end side thereof fixed to the housing part and the other end side thereof being a free end, and a mass part provided to the other end side of the deformation part, the elastic deformation part including a piezoelectric element that reciprocally converts a deformation amount of the elastic deformation part and electric power.

5. The valve device according to claim 4, wherein
the power-generating unit is in an interior of the actuator, and the elastic deformation part is formed into an annular shape or an arc shape along an outer contour of the movable part.

6. The valve device according to claim 2, wherein
a vibration system of the power-generating and vibration-damping unit comprises an elastic deformation part having a cantilevered shape with one end side thereof fixed to the housing part and the other end side thereof being a free end, and a mass part provided to the other end side of the deformation part, the elastic deformation part including a piezoelectric element that reciprocally converts a deformation amount of the elastic deformation part and electric power.

7. The valve device according to claim 6, wherein
the power-generating unit is in an interior of the actuator, and the elastic deformation part is formed into an annular shape or an arc shape along an outer contour of the movable part.
